(19) United States
(12) Patent Application Publication
(10) Pub. No.: US 2010/0294331 A1
(43) Pub. Date: Nov. 25, 2010

(54) PHOTOVOLTAIC ELECTRICAL ENERGY GENERATING SYSTEM

(76) Inventor: Richard E. Carnation, Windsor, CA (US)

Correspondence Address: Bay Area Technology Law Group PC, Suite 404, 500 Sansome Street, San Francisco, CA, 94111, US

(21) Appl. No.: 12/701,115

(22) Filed: Feb. 5, 2010

(51) Int. Cl. H01L 31/042; F24J 2/42

(52) U.S. Cl. 136/244; 126/561

(57) ABSTRACT

A system for the generation of electric power for use in connection with a water feature, such as a swimming pool, lake, pond and the like. The system includes an array of photovoltaic cells within a continuous membrane or joined to a separate membrane, the membrane being sized to fit atop or within the water feature when exposing the photovoltaic cells to ambient light.

### TECHNICAL FIELD

The present invention involves a novel system for the generation of electric power. Water features, such as swimming pools, lakes and ponds, by their very nature, have significant surface areas which, for the most part, remain unused. The present invention suggests that electric power can be generated by taking advantage of such water features by positioning an array of photovoltaic cells on or within such areas for exposure to ambient light.

### BACKGROUND OF THE INVENTION

Photovoltaics involve the application of solar cells for energy by converting sunlight including sun ultraviolet radiation directly into electricity. Photovoltaic production is perhaps the fastest growing form of energy technology whose use is doubling each year.

Solar cells are commonly employed on the roof tops of buildings. Oftentimes, however, a building owner might resist the use of photovoltaics to generate energy for aesthetic reasons and because of the significant cost associated with installing devices which use this technology. Such devices include the packaging of multiple photovoltaic modules creating photovoltaic arrays. These arrays receive photons from sunlight increasing electrons to higher energy states thereby creating electricity. These photodiodes create current entirely due to transduced light energy.

The first practical application of photovoltaics was to power orbiting satellites and other spacecraft while today these devices are used for grid connected power generation. When this is done, an inverter is used to convert the DC to AC for residential, commercial and industrial use. There is also a smaller market for off grid power for remote dwellings, roadside emergency telephones, remote sensing and cathodic protection of pipelines.

When photovoltaic cells require protection from the environment, they are usually packaged tightly behind a glass sheet. To increase power, cells are electrically connected together to form photovoltaic modules or solar panels. Newer alternatives to standard crystal and silicone module manufacturing techniques include casting wafers, thin film fabrication (CdIe, CIGS, amorphous Si, microcrystalline Si), concentrator modules, “silver” cells, and continuous printing processes. Photovoltaics are available as thin plastic sheathing from companies such as Innovative Solar Technologies. As such, they can be made as continuous membranes having individual photovoltaic cells contained therein, or as separate cells connected to one another electrically thus creating either a stand alone membrane or a series of slats or “shingles” which can be used in conjunction with one another for suitable energy production.

As noted previously, it is common, in either residential or commercial facilities, to place solar panels containing photovoltaic cells on the rooftop of a structure as this is bound to capture more ambient light energy than in comparable locations. Clearly, positioning is dictated by the need to expose the photovoltaic panel skyward to receive the most unobstructed sunlight for the majority of the day. Further, although surface area is a primary consideration and rooftops may be restricted in this regard, at least solar panels placed on roofs are less likely to be obstructed by ground surface features.

Despite the obvious benefits of placing photovoltaic arrays on rooftops, such placement is not within its drawbacks. Among them is the recognition that preexisting buildings are not always situated such that their roofs capture the most amount of ambient light that might otherwise be available. Further, roofs have limited surface areas as they were built not necessarily to capture maximum ambient light energy but to simply act as a secure covering for a structure or dwelling In addition, solar panels incorporating photovoltaic arrays can be expensive to install requiring a skilled applicator and significant dedicated hardware to accomplish the task. Even when done professionally, such installations can result in roof leakage and structural compromise beyond the fact that, as noted, in residential settings, solar panels are oftentimes considered too “industrial” a look to justify the implementation.

It has now been recognized through the present invention that there remains an untapped area for the application of photovoltaics which may be far superior to current installations. For example, in residential settings, many homeowners own swimming pools which are not only placed in sunny portions of one's property but exhibit large surface areas which for most of the time remain coveted with one's standard pool cover. These pool covers are used as a security feature preventing unwanted access by infants, larger persons, pets and debris. Additional benefits include absorbing sunlight to heat the pools as well as to prevent debris, such as leaves, from intruding within them. It is has now been determined that with the advent of thin film photovoltaic cells and other electricity generating processes the surface of a water feature, such as a swimming pool, pond or lake including a waste water pond would be an ideal environment in which to place one or more photovoltaic elements for the generation of electrical energy heretofore untapped.

### SUMMARY OF THE INVENTION

A system for the generation of electric power for use in connection with a water feature, such as a swimming pool, lake, pond and the like. The system includes an array of photovoltaic cells within a continuous membrane or joined to a separate membrane, the membrane being sized to fit atop or within the water feature when exposing the photovoltaic cells to ambient light.

### BRIEF DESCRIPTION OF THE FIGURES

FIG. 1 is a perspective view of a typical in ground swimming pool having the present invention installed therein.

FIGS. 2a, 2b, 2c and 2d are examples of typical photovoltaic cell arrays taken along line 2-2 of FIG. 1.

FIG. 3 is a top plan view of a typical water feature, such as a lake or pond having the present system installed therein.

FIGS. 4a, 4b, 4c and 4d are cross sectional views of various vault installations showing how swimming pool covers are typically stored, all of which can be used in implementing the present invention.

### DETAILED DESCRIPTION OF THE INVENTION

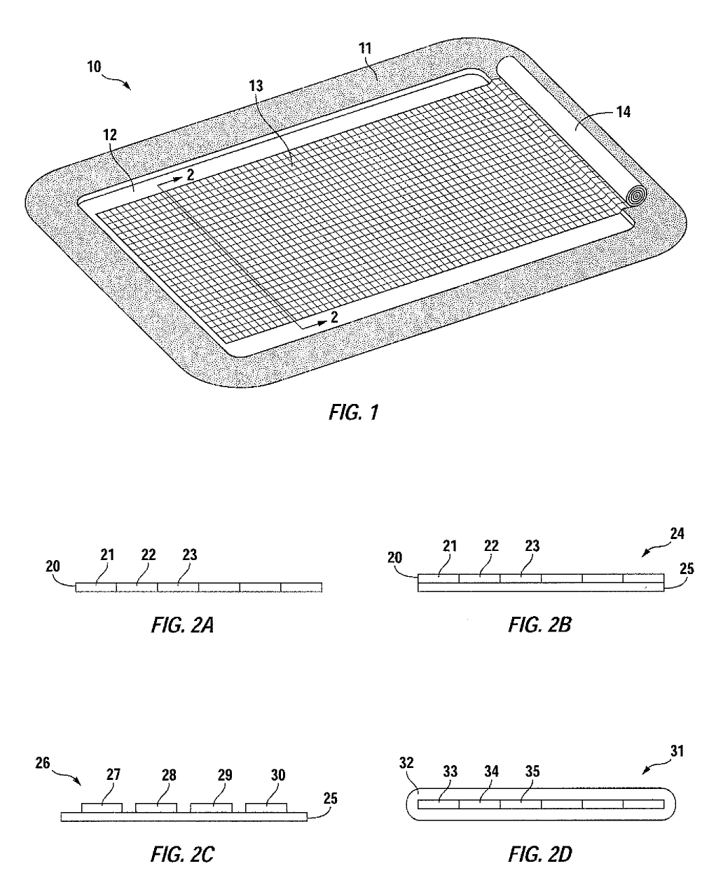

The present invention involves a system for the generation of electric power for use in connection with a water feature. In turning to FIG. 1, one such water feature is shown in the form of an in ground swimming pool 10 commonly in use both domestically and commercially. Swimming pool 10 is surrounded by walkway 11, generally of concrete or composite material containing water body 12.

As stated previously, in order to maintain security and safety, increase pool temperature as well as to reduce debris accumulation within water body 12, pool cover 13 is drawn over virtually the entire surface area of pool 10 when the pool is not in use. Under ordinary circumstances, cover 13 is of a plastic composition and ideally floats atop water body 12 for its stated purposes. To assist in payout and removal of pool cover 13, roller 14 is provided which can either be turned mechanically or through motor actuation providing a neat roll when water body 12 is exposed for use.

However, unlike prior art pool covers, the present system is capable of not only protecting water body 12 from the intrusion of debris, unwanted swimmers and water temperature elevation and conservation but also of generating electrical DC power. This is done by using as either a stand alone membrane of photovoltaic cells or as individual cells joined to a supporting membrane to constitute the cover. Again, the photovoltaic cells can be continuous sheet material or individualized elements which are electrically joined. In this regard, reference is made to FIG. 2.

FIGS. 2a-2d show, in cross section, various alternative embodiments constituting the appropriate cover useful in practicing the present invention. For example, in turning to FIG. 2a, a single sheet of flexible photovoltaic material made up of individual cells continuously arranged thereon is shown as membrane 20 having cells 21, 22, 23, etc., situated therein. As noted previously, membranes of this type are available commercially. One such manufacturer is Innovative Solar Technologies. Membrane 20 can be used alone as pool cover 13 installed as shown in FIG. 1. Alternatively, as noted in reference to FIG. 2b, membrane 13 can comprise composite 24 whereby membrane 20 as described with reference to FIG. 2a having continuous photovoltaic cells 21, 22, 23, etc., is bonded to membrane 25 which can be something as common as a preexisting pool cover enabling composite 24 to reside on top of or submerged within water body 12.

As yet a third embodiment, pool cover 13 can be composed of membrane 26 as shown in FIG. 2c. In this embodiment, support membrane 25 can act as a cover for pool 10 and include individualized slats or shingles of photovoltaic cells 27, 28, 29 and 30 electrically connected to one another or to a common interface for the collection of DC power located proximate to the water feature.

Finally, pool cover 13 can be composed of membrane 31 including protective sheathing 32 surrounding photovoltaic cells 33, 34, 35, etc which can either be individual cells (FIG. 2c) or a continuous film of cells (FIGS. 2a and 2b). The configuration of FIG. 2d offers the advantage of protecting the photovoltaic material in environments where the water feature may cause degradation of the photovoltaic cells prematurely were such protection was not provided.

Up to this point, the invention has been described in terms of a swimming pool cover such as cover 13 of FIG. 1. However, recognizing that other water features can be equally suitable for the implementation of the present invention, reference is made to FIG. 3.

In turning to FIG. 3, water feature 40 is shown in the form of a lake, waste water or fresh pond or the like. Membrane 42 can be cast or otherwise drawn over all or a portion of water mass 41 presenting a substantial area from which photovoltaic energy can be gathered. Energy so gathered within membrane 42 can be communicated via lines 43 to transfer box 44 in which the energy can either be transferred as DC or converted to AC as needed.

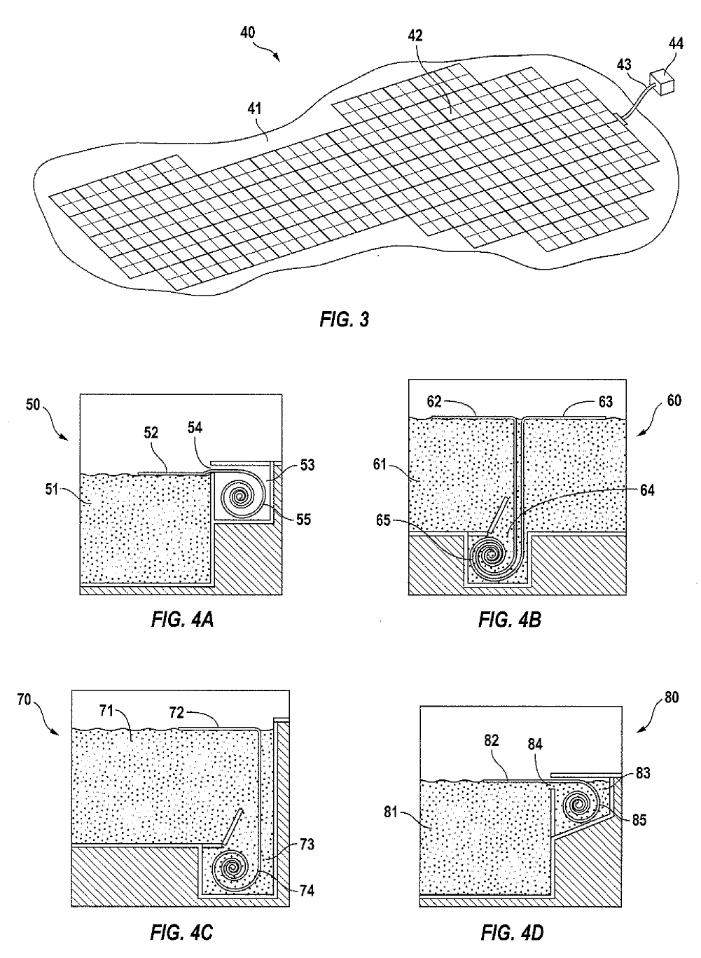

Turning back to the swimming pool environment, reference is made to FIG. 4 showing alternative embodiments typical of how pool covers are stored and deployed.

In turning to FIG. 4a, pool 50 is shown in partial cross section having water body 51 and appended vault 55 housing toll 53 of pool cover membrane material. Membrane 52 is paid out from roll 53 through opening 54 in vault 55. All photovoltaic membrane embodiments of the present invention can constitute membrane 52. A similar configuration is shown in FIG. 4d where vault 83 is situated within pool 80 adjacent water body 81 housing roll 85 with membrane material 82 paid out or drawn within vault 85 through opening 84.

FIGS. 4b and 4c show arrangements in which membrane 61-63 (FIG. 4b) or membrane 72 (FIG. 4c) is paid out from roll 65 and 70, respectively for a position at the bottom of water bodies 61-71. These embodiments used within pools 60 and 70 show the use of the pay out of singular membrane 72 floating atop water body 71 in the case of the embodiment of FIG. 4c or the pay out of dual membranes 62-63 in the case of the embodiment of FIG. 4b. All of the embodiments of FIG. 4 are suitable for the containment of the photovoltaic membranes of the present invention such that the basic figuration of standard pools need not be modified to embody this invention on a broad scale.

What is claimed is:

1. A system for the generation of electric power for use in connection with a water feature comprising an array of photovoltaic cells joined to a membrane, said membrane sized to fit atop or within said water feature when exposing said photovoltaic cells to ambient light.

2. The system of claim 1 wherein said water feature comprises a swimming pool.

3. The system of claim 2 wherein said membrane comprises a cover selectively covering said swimming pool when not in use.

4. The system of claim 3 wherein said cover is appended to a roller.

5 The system of claim 4 wherein said roller is actuated by a motor for facilitating the selective payout and storage of said cover.

6. The system of claim 3 wherein said array of photovoltaic cells comprises a continuous thin film mated to said membrane forming said cover.

7. The system of claim 3 wherein said array of photovoltaic cells comprises a plurality of thin films mated to said membrane forming said cover.

8 The system of claim 1 wherein said membrane, when in use, floats atop said water feature.

9. The system of claim 1 wherein said membrane submerges within said water feature when in use

10. The system of claim 1 wherein said water feature comprises a member selective from the group consisting of lakes, fresh, saline and waste water ponds.

11. The system of claim 1 further comprising a storage vault for housing said membrane when not in use.

12. A membrane for the conversion of ambient sunlight to electric power for use in connection with a water feature comprising a plurality of photovoltaic cells in the form of a continuous array, said array sized to fit atop or within said water feature when exposing said photovoltaic cells to said ambient light.

13 The membrane of claim 12 wherein said water feature comprises a swimming pool.

14. The membrane of claim 13 comprising a cover for selectively covering said swimming pool when not in use.

15. The membrane of claim 14 wherein said cover is appended to a roller.

16. The membrane of claim 15 wherein said roller is actuated by a motor for facilitating a selective payout and storage of said cover.

17. The membrane of claim 12 wherein said water feature comprises a member selected from the group consisting of lakes, fresh, saline and waste water ponds.

18. A system for the conversion of ambient light to electric power for use in connection with a water feature comprising a plurality of individual photovoltaic cells, each of said cells being joined to a continuous membrane, said membrane sized to fit atop or within said water feature when exposing said voltaic cells to said ambient light

19. The system of claim 18 wherein said water feature comprises a swimming pool

20. The system of claim 19 wherein said continuous membrane comprises a cover for selectively covering said swimming pool when not in use.

21 The system of claim 20 wherein said cover is appended to a roller.

22. The system of claim 21 wherein said roller is actuated by a motor for facilitating the selective payout and storage of said cover.

23. The system of claim 18 wherein said water feature comprises a member selected from the group consisting of lakes, fresh, saline and waste water ponds.
